(19) United States
(12) Patent Application Publication
(10) Pub. No.: US 2015/0223340 A1
(43) Pub. Date: Aug. 6, 2015

(54) MULTILAYER CERAMIC ELECTRONIC COMPONENT TO BE EMBEDDED IN BOARD, MANUFACTURING METHOD THEREOF, AND PRINTED CIRCUIT BOARD HAVING MULTILAYER CERAMIC ELECTRONIC COMPONENT

(71) Applicant: SAMSUNG ELECTRO-MECHANICS CO., LTD., Suwon-Si (KR)

(72) Inventors: Jin Man JUNG, Suwon-Si (KR); Doo Young KIM, Suwon-Si (KR); Byoung Hwa LEE, Suwon-Si (KR); Young Don CHOI, Suwon-Si (KR); Eun Hyuk CHAE, Suwon-Si (KR)

(73) Assignee: SAMSUNG ELECTRO-MECHANICS CO., LTD., Suwon-Si (KR)

(21) Appl. No.: 14/266,091

(22) Filed: Apr. 30, 2014

(30) Foreign Application Priority Data
Feb. 3, 2014 (KR) 10-2014-0012189

(51) Int. Cl. H05K 1/18; H01G 4/008; H05K 1/09; H01G 4/12; H05K 1/03; H01G 4/30; H01G 4/012

(52) U.S. Cl. CPC H05K 1/183; H01G 4/30; H01G 4/008; H01G 4/012; H01G 4/12; H05K 1/0306; H05K 1/09; H05K 2201/10015

(57) ABSTRACT

In a multilayer ceramic electronic component to be embedded in a board, a thickness of a ceramic body in an overall chip may be increased by not allowing an increase in a thickness of an external electrode to occur, while forming a band surface of the external electrode having a predetermined length or greater for connecting the external electrode to an external wiring through a via hole, thereby improving chip strength and preventing the occurrence of damage such as breakage, or the like, a manufacturing method thereof, and a printed circuit board having the multilayer ceramic electronic component.

### CROSS-REFERENCE TO RELATED APPLICATION

This application claims the benefit of Korean Patent Application No. 10-2014-0012189 filed on Feb. 3, 2014, with the Korean Intellectual Property Office, the disclosure of which is incorporated herein by reference.

### BACKGROUND

The present disclosure relates to a multilayer ceramic electronic component to be embedded in a board, a manufacturing method thereof, and a printed circuit board having a multilayer ceramic electronic component.

As electronic circuits have become highly densified and highly integrated, a mounting space for passive elements mounted on a printed circuit board (PCB) has become insufficient, and in order to solve this limitation, ongoing efforts have been made to implement components able to be installed within a board, i.e., embedded devices. In particular, various methods have been proposed for installing a multilayer ceramic electronic component used as a capacitive component within a board.

In one of a variety of methods of installing a multilayer ceramic electronic component within a board, the same dielectric material used for a multilayer ceramic electronic component is used as a material for a board and a copper wiring, or the like, is used as an electrode for the multilayer ceramic electronic component. Other methods for implementing a multilayer ceramic electronic component to be embedded in a board include a method of forming the multilayer ceramic electronic component to be embedded in the board by forming a polymer sheet having high-k dielectrics and a dielectric thin film within the board, a method of installing a multilayer ceramic electronic component within a board, and the like.

In general, a multilayer ceramic electronic component includes a plurality of dielectric layers made of a ceramic material, and internal electrodes interposed between the dielectric layers. By disposing such a multilayer ceramic electronic component within a board, a high capacitance multilayer ceramic electronic component to be embedded in a board may be implemented.

After the multilayer ceramic electronic component is embedded in the board, a via hole is formed such that an external electrode of the multilayer ceramic electronic component is exposed by penetrating through a resin using laser, and the via hole is filled with a copper plating to electrically connect an external wiring and the external electrode of the multilayer ceramic electronic component to each other.

In this case, in order to connect the external electrode of the multilayer ceramic electronic component and the external wiring through the via hole, there is a need to form a band surface of the external electrode having a predetermined length or greater. However, in a case in which the band surface of the external electrode having a predetermined length or greater is formed using an existing dipping method, or the like, a thickness of the external electrode becomes thick, such that a ceramic body having a sufficient thickness may not be secured by an increase in the thickness of the external electrode. Since the multilayer ceramic electronic component to be embedded in a board has an overall chip thickness smaller than that of a multilayer ceramic electronic component not to be embedded in a board, in a case in which the band surface of the external electrode is formed to have a large thickness, the thickness of the ceramic body may be very small, such that chip strength may be lowered and damage may be caused thereto.

In addition, when a step portion due to a difference in thicknesses between the ceramic body and the external electrode of the multilayer ceramic electronic component is increased, a gap between the multilayer ceramic electronic component and a film is increased, such that the probability of the occurrence of delamination is further increased. Therefore, in order to decrease delamination, it is necessary to decrease the thickness of the external electrode.

### RELATED ART DOCUMENT

(Patent Document 1) Korean Patent Laid-Open Publication No. KR 2011-0122008

### SUMMARY

An aspect of the present disclosure may provide a multilayer ceramic electronic component to be embedded in a board, in which a thickness of a ceramic body in an overall chip is increased by not allowing an increase in a thickness of an external electrode to occur, while forming a band surface of the external electrode having a predetermined length or greater for connecting the external electrode to an external wiring through a via hole, a manufacturing method thereof, and a printed circuit board having a multilayer ceramic electronic component.

According to an aspect of the present disclosure, a multilayer ceramic electronic component to be embedded in a board may include: a ceramic body including dielectric layers and having both end surfaces in a length direction, both surfaces in a width direction, and both surfaces in a thickness direction; first and second internal electrodes formed to be alternately exposed to the both end surfaces of the ceramic body in the length direction, having the dielectric layers interposed therebetween; conductive pattern layers formed on at least one surface of the ceramic body in the thickness direction; and first and second external electrodes formed on the both end surfaces of the ceramic body in the length direction, the first external electrode being electrically connected to the first internal electrode and the second external electrode being electrically connected to the second internal electrode, wherein the first and second external electrodes are extended onto the conductive pattern layers formed on the least one surface of the ceramic body in the thickness direction.

A thickness of the ceramic body may be equal to or greater than 80% of an overall thickness of the multilayer ceramic electronic component including the external electrodes.

An overall thickness of the multilayer ceramic electronic component including the external electrodes may be 110 μm or less.

The conductive pattern layers may contain at least one selected from a group consisting of copper (Cu), nickel (Ni), palladium (Pd), platinum (Pt), gold (Au), silver (Ag), and lead (Pb).

When a thickness of band surfaces of the first and second external electrodes extended onto the conductive pattern layers and formed on the least one surface of the ceramic body in the thickness direction is defined as tp, tp≦20 μm may be satisfied.

The conductive pattern layers may be formed to be separated from each other on both end portions of the at least one surface of the ceramic body in the thickness direction.

When widths of band surfaces of the first and second external electrodes extended onto the conductive pattern layers and formed on the at least one surface of the ceramic body in the thickness direction are defined as BW1 and BW2, each of BW1 and BW2 may be equal to or greater than 35% of a length of the ceramic body.

The conductive pattern layers and the first and second external electrodes extended onto the conductive pattern layers may only formed on one surface of the ceramic body in the thickness direction.

The ceramic body may include an active layer including the first and second internal electrodes to form capacitance; and upper and lower cover layers formed on upper and lower portions of the active layer, and when a thickness of the cover layer adjacent to one surface of the ceramic body on which the band surfaces of the first and second external electrodes are extended onto the conductive pattern layers is defined as tc1 and a thickness of the cover layer adjacent to the other surface of the ceramic body on which the band surfaces of the first and second external electrodes are not formed is defined as tc2, tc1/tc2 may be less than 1.

The first and second external electrodes extended onto the conductive pattern layers may be formed by plating process.

According to another aspect of the present disclosure, a multilayer ceramic electronic component to be embedded in a board may include: a ceramic body including dielectric layers and having both end surfaces in a length direction, both surfaces in a width direction, and both surfaces in a thickness direction; first and second internal electrodes formed to be alternately exposed to the both end surfaces of the ceramic body in the length direction, having the dielectric layers interposed therebetween; conductive pattern layers formed on at least one surface of the ceramic body in the thickness direction; and first and second external electrodes formed on the both end surfaces of the ceramic body in the length direction, the first external electrode being electrically connected to the first internal electrode and the second external electrode being electrically connected to the second internal electrode, wherein the first and second external electrodes include first and second base electrodes formed on the both end surfaces of the ceramic body in the length direction and plating layers formed on the first and second base electrodes, the plating layers being extended onto the conductive pattern layers formed on the least one surface of the ceramic body in the thickness direction.

According to another aspect of the present disclosure, a manufacturing method of a multilayer ceramic electronic component to be embedded in a board may include: preparing a plurality of ceramic sheets; forming an internal electrode pattern on each of the ceramic sheets using a conductive paste; forming a ceramic body including first and second internal electrodes opposed to each other therein by stacking the ceramic sheets having the internal electrode pattern formed thereon; compressing and sintering the ceramic body; and forming conductive patterns on at least one surface of the ceramic body in a thickness direction using the conductive paste; and forming first and second external electrodes to contact the first and second internal electrodes exposed to both end surfaces of the ceramic body in a length direction to thereby be electrically connected thereto, wherein the first and second external electrodes are formed to be extended onto the conductive patterns formed on the at least one surface of the ceramic body in the thickness direction.

The forming of the first and second external electrodes may include forming first and second base electrodes on the both end surfaces of the ceramic body in the length direction and forming plating layers on the first and second base electrodes and the conductive patterns.

The conductive paste for forming the conductive patterns may contain at least one selected from a group consisting of copper (Cu), nickel (Ni), palladium (Pd), platinum (Pt), gold (Au), silver (Ag), and lead (Pb).

The forming of the conductive patterns may include: disposing sheets having the conductive patterns formed on one surfaces thereof on both surfaces of the ceramic body in the thickness direction, the conductive patterns being disposed in the same direction; and removing an outermost sheet disposed on one surface of the ceramic body in the thickness direction, among the sheets having the conductive patterns disposed on the both surfaces of the ceramic body in the thickness direction to thereby expose the conductive patterns.

The conductive patterns may be formed to be separated from each other on both end portions of the at least one surface of the ceramic body in the thickness direction.

According to another aspect of the present disclosure, a printed circuit board having a multilayer ceramic electronic component may include: an insulation substrate; and the multilayer ceramic electronic component embedded in the board and including a ceramic body including dielectric layers and having both end surfaces in a length direction, both surfaces in a width direction, and both surfaces in a thickness direction; first and second internal electrodes formed to be alternately exposed to the both end surfaces of the ceramic body in the length direction, having the dielectric layers interposed therebetween; conductive pattern layers formed on at least one surface of the ceramic body in the thickness direction; and first and second external electrodes formed on the both end surfaces of the ceramic body in the length direction, the first external electrode being electrically connected to the first internal electrode and the second external electrode being electrically connected to the second internal electrode, wherein the first and second external electrodes are extended onto the conductive pattern layers formed on the least one surface of the ceramic body in the thickness direction.

A thickness of the ceramic body may be equal to or greater than 80% of an overall thickness of the multilayer ceramic electronic component including the external electrodes.

An overall thickness of the multilayer ceramic electronic component including the external electrodes may be 110 μm or less.

When widths of band surfaces of the first and second external electrodes extended onto the conductive pattern layers and formed on the at least one surface of the ceramic body in the thickness direction are defined as BW1 and BW2, each of BW1 and BW2 may be equal to or greater than 35% of a length of the ceramic body.

The conductive pattern layers and the first and second external electrodes extended onto the conductive pattern layers may be only formed on one surface of the ceramic body in the thickness direction.

The ceramic body may include an active layer including the first and second internal electrodes to form capacitance; and upper and lower cover layers formed on upper and lower portions of the active layer, and when a thickness of the cover layer adjacent to one surface of the ceramic body on which the band surfaces of the first and second external electrodes are extended onto the conductive pattern layers is defined as tc1 and a thickness of the cover layer adjacent to the other surface of the ceramic body on which the band surfaces of the first and second external electrodes are not formed is defined as tc2, tc1/tc2 may be less than 1.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view showing a multilayer ceramic electronic component to be embedded in a board according to an exemplary embodiment of the present disclosure;

FIG. 2 is a perspective view schematically showing the multilayer ceramic electronic component to be embedded in a board according to the exemplary embodiment of the present disclosure, except for external electrodes thereof;

FIG. 3 is a cross-sectional view showing the multilayer ceramic electronic component to be embedded in a board according to the exemplary embodiment of the present disclosure, taken along line X-X′ of FIG. 1;

FIG. 4 is a cross-sectional view illustrating an example of the multilayer ceramic electronic component to be embedded in a board according to the exemplary embodiment of the present disclosure;

FIG. 5 is a cross-sectional view illustrating another example of the multilayer ceramic electronic component to be embedded in a board according to the exemplary embodiment of the present disclosure;

FIG. 6 is a cross-sectional view illustrating another example of the multilayer ceramic electronic component to be embedded in a board according to the exemplary embodiment of the present disclosure;

FIG. 7 is a view schematically showing a process of forming conductive patterns on a ceramic body according to an exemplary embodiment of the present disclosure; and

FIG. 8 is a cross-sectional view showing a printed circuit board having the multilayer ceramic electronic component according to an exemplary embodiment of the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Directions in a hexahedron will be defined in order to clearly describe exemplary embodiments of the present disclosure. L, W and T shown in the drawings refer to a length direction, a width direction, and a thickness direction, respectively. Here, the thickness direction may be used to have the same concept as a direction in which dielectric layers are stacked.

Multilayer Ceramic Electronic Component to be Embedded in Board

Hereinafter, a multilayer ceramic electronic component to be embedded in a board according to an exemplary embodiment of the present disclosure will be described. Particularly, a multilayer ceramic capacitor to be embedded in a board will be described by way of example. However, the present disclosure is not limited thereto.

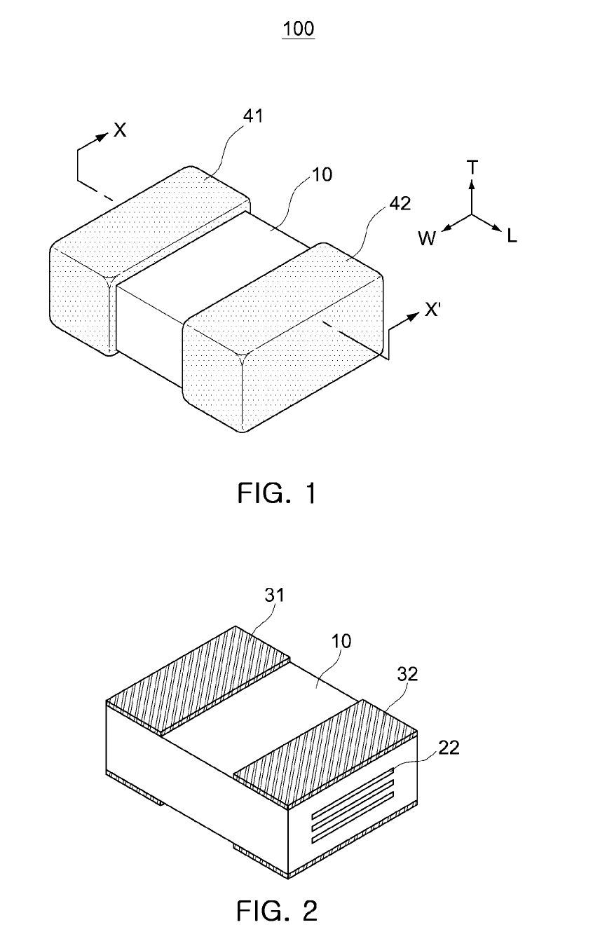

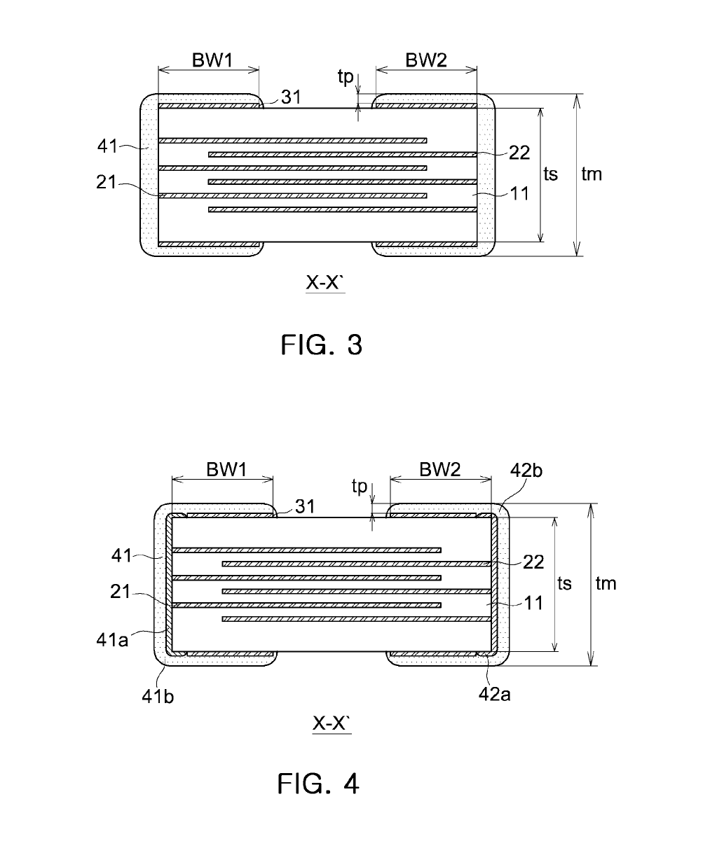

FIG. 1 is a perspective view showing a multilayer ceramic electronic component to be embedded in a board according to an exemplary embodiment of the present disclosure. FIG. 2 is a perspective view schematically showing the multilayer ceramic electronic component to be embedded in a board according to the exemplary embodiment of the present disclosure, except for external electrodes thereof. FIG. 3 is a cross-sectional view showing the multilayer ceramic electronic component to be embedded in a board according to the exemplary embodiment of the present disclosure, taken along line X-X′ of FIG. 1;

Referring to FIGS. 1 through 3, a multilayer ceramic electronic component 100 to be embedded in a board according to an exemplary embodiment of the present disclosure may include a ceramic body 10, first and second internal electrodes 21 and 22, conductive pattern layers 31 and 32, and first and second external electrodes 41 and 42.

The ceramic body 10 may be formed in a hexahedral shape having both end surfaces in the length direction L, both surfaces in the width direction W, and both surfaces in the thickness direction T. The ceramic body 10 may be formed by stacking a plurality of dielectric layers 11 in the thickness direction T and then sintering the same, and a shape and dimensions of the ceramic body 10, and the number of the stacked dielectric layers 11 are not limited to those shown in the exemplary embodiment of the present disclosure.

In addition, the plurality of dielectric layers 11 configuring the ceramic body 10 may be in a sintered state. The dielectric layers 11 adjacent to each other may be integrated so as not to confirm a boundary therebetween without using a scanning electron microscope (SEM).

The dielectric layers 11 may have a thickness capable of being arbitrarily changed according to a capacitance design of the multilayer ceramic electronic component 100 and may include a ceramic powder having a high dielectric constant, for example, a barium titanate (BaTiO₃) based powder or a strontium titanate (SrTiO₃) based powder, but the present disclosure is not limited thereto. In addition, various ceramic additives, organic solvents, plasticizers, binders, dispersing agents, or the like, may be added to the ceramic powder according to the object of the present disclosure.

An average particle diameter of the ceramic powder used for forming the dielectric layers 11 is not particularly limited, may be adjusted in order to achieve the object of the present disclosure, and for example, may be adjusted to 400 nm or less.

The first and second internal electrodes 21 and 22, pairs of electrodes having different polarities, may be formed in the stacking direction of the plurality of dielectric layers 11 so as to be alternately exposed through both end surfaces of the ceramic body 10 in the length direction L by printing a conductive paste containing a conductive metal at a predetermined thickness on the plurality of dielectric layers 11 stacked in the thickness direction T, and may be insulated from each other by the dielectric layers 11 disposed therebetween.

That is, the first and second internal electrodes 21 and 22 may be electrically connected to the first and second external electrodes 41 and 42 formed on both end surfaces of the ceramic body 10 in the length direction L, respectively, through portions thereof alternately exposed through both end surfaces of the ceramic body 10.

Therefore, when a voltage is applied to the first and second external electrodes 41 and 42, electrical charges are accumulated between the first and second internal electrodes 21 and 22 opposed to each other. In this case, a capacitance of the multilayer ceramic capacitor 100 is proportional to an area of a region in which the first and second internal electrodes 21 and 22 are overlapped with each other.

The first and second internal electrodes 21 and 22 may have widths determined according to an intended use thereof and may have widths in a range of 0.2 to 1.0 μm determined in consideration of a size of the ceramic body 10, for example, but the present disclosure is not limited thereto.

Further, the conductive metal contained in the conductive paste forming the first and second internal electrodes 21 and 22 may be nickel (Ni), copper (Cu), palladium (Pd), silver (Ag), lead (Pb), platinum (Pt), or the like, alone, or alloys thereof, but the present disclosure is not limited thereto.

The conductive pattern layers 31 and 32 may be formed on at least one surface of the ceramic body 10 in the thickness direction T by printing a conductive paste containing a conductive metal at a predetermined thickness, and may be formed to be separated from each other on both end portions of the least one surface of the ceramic body in the thickness direction T, respectively. The conductive metal contained in the conductive paste for forming the conductive pattern layers 31 and 32 may be the same as that of the first and second internal electrodes 21 and 22, but the present disclosure is not limited thereto. For example, the conductive metal may be copper (Cu), nickel (Ni), palladium (Pd), platinum (Pt), gold (Au), silver (Ag), lead (Pb), or the like, alone, or alloys thereof.

In a method of forming external electrodes according to the related art, a method of dipping the ceramic body in a paste including metal components is mainly used. In this case, a multilayer ceramic capacitor to be embedded in a board needs to have band surfaces of the external electrodes having a predetermined length or greater in order to connect the external electrode and an external wiring through a via hole. However, according to the dipping method according to the related art, the left and right band surfaces may be thickly coated due to interfacial tension of the paste.

Therefore, according to an exemplary embodiment of the present disclosure, the conductive pattern layers 31 and 32 are formed on a surface of the ceramic body 10 in the thickness direction T, such that the band surfaces of the external electrodes 41 and 42 having a predetermined length or greater may be uniformly and more thinly formed on the conductive pattern layers 31 and 32 by plating.

Each of widths BW1 and BW2 of band surfaces of the first and second external electrodes 41 and 42 may be equal to or greater than 35% of a length of the ceramic body 10. In a case in which each of the widths BW1 and BW2 of the band surfaces is less than 35% of the length of the ceramic body 10, probability of the occurrence of defects may be increased during the processing of the via hole for connecting the external electrode to the external wiring.

When a thickness of the band surfaces of the external electrodes 41 and 42 extended onto the conductive pattern layers 31 and 32 and formed on the surface of the ceramic body 10 in the thickness direction T is defined as tp, tp≦20 μm may be satisfied. In a case in which tp is greater than 20 μm, since a thickness of the ceramic body may be reduced by an amount equal to an increase in the thickness of the band surfaces of the external electrodes, such that chip strength may be lowered. In particular, since the multilayer ceramic electronic component to be embedded in a board has an overall chip thickness smaller than that of a multilayer ceramic electronic component not to be embedded in a board, securing the thickness of the ceramic body to have chip strength capable of preventing damage, and the like, may be important.

Meanwhile, in a case in which the thickness tp of the band surfaces of the external electrodes is extremely small, probability of the occurrence of defects may be increased during the processing of the via hole for connecting the external electrode to the external wiring, and a plating solution or the like may infiltrate into the ceramic body. Therefore, the thickness tp of the band surfaces of the external electrodes may preferably satisfy 5 μm≦tp≦20 μm.

An overall thickness tm of the multilayer ceramic capacitor 100 including the external electrodes 41 and 42 may be 110 μm or less, and the multilayer ceramic capacitor 100 is manufactured to have the overall thickness tm of 110 μm or less, such that it may be suitable to be embedded in a board.

In this case, a thickness ts of the ceramic body 10 may be equal to or greater than 80% of the overall thickness tm of the multilayer ceramic capacitor including the external electrodes 41 and 42. In a case in which the thickness ts of the ceramic body 10 is less than 80% of the overall thickness tm of the multilayer ceramic capacitor, chip strength may be lowered, such that defects such as damage and the like may occur.

The first and second external electrodes 41 and 42 may be formed on both end surfaces of the ceramic body 10 in the length direction L, and may be extended onto the conductive pattern layers 31 and 32 formed on the surface of the ceramic body 10 in the thickness direction T to thereby form the band surfaces. The first and second external electrodes 41 and 42 may be formed of the same conductive metal as that of the first and second internal electrodes 21 and 22, but the present disclosure is not limited thereto. For example, the conductive metal may be copper (Cu), silver (Ag), nickel (Ni), or the like, alone, or alloys thereof.

The band surfaces of the first and second external electrodes 41 and 42 formed on the conductive pattern layers 31 and 32 may be formed by a plating process using the conductive pattern layers 31 and 32 as seed layers, and head surfaces of the first and second external electrodes 41 and 42 formed on both end surfaces of the ceramic body 10 in the length direction L may be formed by a dipping method, a plating method, and the like, but the present disclosure is not limited thereto.

FIG. 4 is a cross-sectional view illustrating an example of the multilayer ceramic electronic component to be embedded in a board according to the exemplary embodiment of the present disclosure.

Referring to FIG. 4, the first and second external electrodes 41 and 42 formed on both end surfaces of the ceramic body 10 in the length direction L, which are electrically connected to the first and second internal electrodes 21 and 22, may include first and second base electrodes 41a and 42a and plating layers 41b and 42b formed on the first and second base electrodes 41a and 42a, and the plating layers 41b and 42b may be extended onto the conductive pattern layers 31 and 32 formed on the surface of the ceramic body 10 in the thickness direction T.

A method of forming the first and second base electrodes 41a and 42a is not particularly limited, but, for example, may be formed by applying the conductive paste containing the conductive metal and then performing a sintering process. The head surfaces and the band surfaces of the first and second external electrodes may be formed by a plating process using the first and second base electrodes 41a and 42a and the conductive pattern layers 31 and 32 as seed layers.

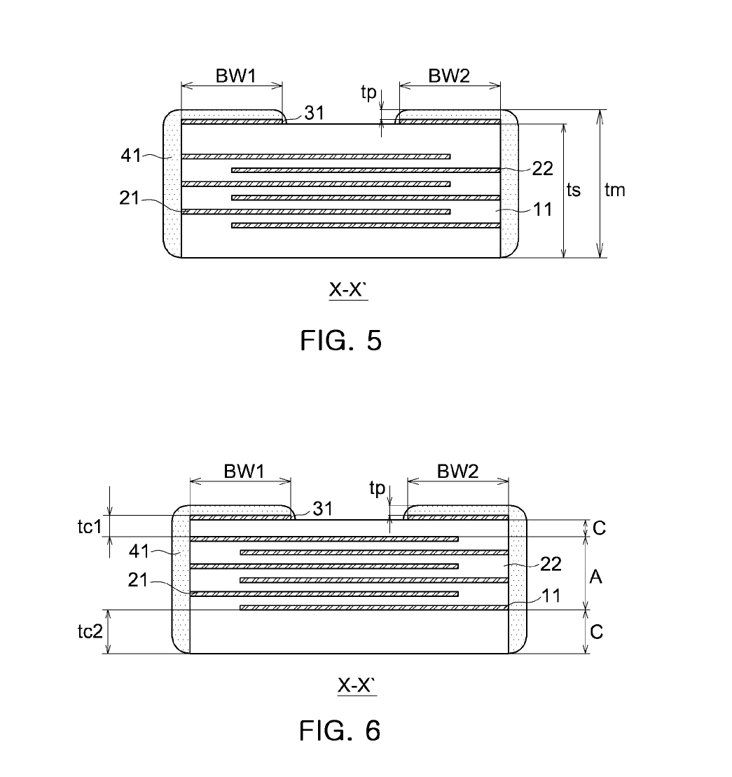

Referring to FIG. 5, a view illustrating a cross-section of a multilayer ceramic capacitor to be embedded in a board according to another exemplary embodiment of the present disclosure, the band surfaces of the first and second external electrodes formed on the conductive pattern layers 31 and 32 may be only formed on one surface of the ceramic body 10 in the thickness direction T.

Unlike existing dipping methods, the conductive pattern layers 31 and 32 may be only formed on one surface of the ceramic body 10 in the thickness direction T, and the band surfaces of the external electrodes may be only formed on one surface of the ceramic body 10 in the thickness direction T by plating, such that the thickness of the ceramic body 10 may be increased by an amount in which the band surfaces of the external electrodes are not formed on the other surface of the ceramic body 10, thereby improving chip strength.

Referring to FIG. 6, a view illustrating a cross-section of a multilayer ceramic capacitor to be embedded in a board according to another exemplary embodiment of the present disclosure, the ceramic body 10 may include an active layer A as apart contributing to capacitance formation of the capacitor and upper and lower cover layers C formed on upper and lower portions of the active layer A, respectively, to prevent damage of the first and second internal electrodes 21 and 22 due to physical or chemical stress.

The active layer A may be formed by repeatedly stacking the plurality of first and second internal electrodes 21 and 22, having the dielectric layers 11 interposed therebetween. The upper and lower cover layers C may have the same material and configuration as those of the active layer A except that internal electrodes are not included therein.

When a thickness of the cover layer adjacent to one surface of the ceramic body 10 on which the band surfaces of the first and second external electrodes 41 and 42 are extended onto the conductive pattern layers 31 and 32 is defined as tc1 and a thickness of the cover layer adjacent to the other surface of the ceramic body 10 on which the band surfaces of the first and second external electrodes 41 and 42 are not formed is defined as tc2, tc1/tc2 may be less than 1.

The thickness of the cover layer adjacent to the surface of the ceramic body 10 on which the band surfaces of the external electrodes 41 and 42 are formed may be decreased, such that a current path in the multilayer ceramic capacitor to be embedded in a board may be decreased, whereby equivalent series inductance (ESL) may also be decreased.

Manufacturing Method of Multilayer Ceramic Electronic Component Embedded in Board

In a manufacturing method of a multilayer ceramic electronic component to be embedded in a board according to an exemplary embodiment of the present disclosure, a plurality of ceramic green sheets may first be prepared by applying slurry including a barium titanate (BaTiO₃) powder and the like to carrier films and drying the same, thereby forming dielectric layers.

The slurry may be prepared by mixing a ceramic powder, a binder, and a solvent, and the slurry may be used to form the ceramic green sheets each having a thickness of several μm by a doctor blade method.

Next, a conductive paste including a conductive metal power may be prepared. The conductive metal power may be nickel (Ni), copper (Cu), palladium (Pd), silver (Ag), lead (Pb), platinum (Pt), or the like, alone, or an alloy thereof, and may have a particle average size of 0.1 to 0.2 μm, such that the conductive paste for an internal electrode, including the conductive metal power of 40 to 50 wt % may be prepared.

The conductive paste for the internal electrode may be applied to the green sheets by a screen printing method to thereby form an internal electrode pattern. A method of printing the conductive paste may be a screen printing method, a gravure printing method, or the like, but the present disclosure is not limited thereto. The ceramic sheets having the internal electrode pattern printed thereon may be stacked in an amount of 200 to 300 layers, compressed, and then sintered, such that the ceramic body may be fabricated.

Then, the conductive paste may be used to form conductive patterns on at least one surface of the ceramic body in the thickness direction. A conductive metal powder contained in the conductive paste for forming the conductive patterns may be the same as that of internal electrodes, but the present disclosure is not limited thereto. For example, a conductive metal may be copper (Cu), nickel (Ni), palladium (Pd), platinum (Pt), gold (Au), silver (Ag), lead (Pb), or the like, alone, or alloys thereof.

The conductive patterns may be formed to be separated from each other on both end portions of a surface of the ceramic body in the thickness direction T, by a printing method, and the like, using the conductive paste. A method of forming the conductive patterns may include a screen printing method, a gravure printing method, or the like, but the present disclosure is not limited thereto.

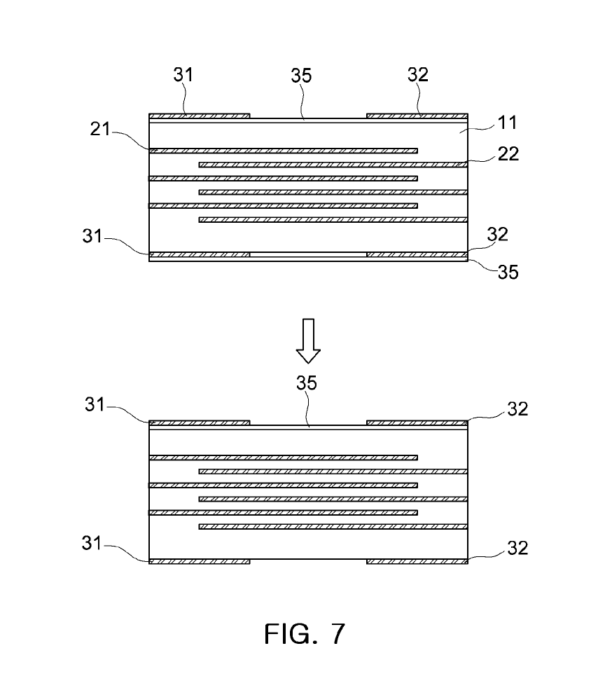

FIG. 7 is a view schematically showing a process of forming conductive patterns on a ceramic body according to an exemplary embodiment of the present disclosure.

Referring to FIG. 7, sheets 35 having the conductive pattern layers 31 and 32 formed on one surfaces thereof are disposed on both surfaces of the ceramic body 10 in the thickness direction T, the conductive pattern layers 31 and 32 thereof being disposed in the same direction and subsequently, an outermost sheet disposed on one surface of the ceramic body 10 in the thickness direction T among the sheets having the conductive pattern layers 31 and 32 disposed on the both surfaces of the ceramic body 10 in the thickness direction T may be removed to expose the conductive pattern layers 31 and 32.

When the conductive patterns are only formed on one surface of the ceramic body in the thickness direction T, the sheet 35 having the conductive pattern layers 31 and 32 formed thereon is only disposed on one surface of the ceramic body 10 in the thickness direction T in such a manner that the conductive pattern layers 31 and 32 are disposed outwardly of the sheet, and the process of removing the sheet 35 may be omitted.

Next, the external electrodes may be formed to contact the internal electrodes exposed to both end surfaces of the ceramic body in the length direction to thereby be electrically connected thereto. The external electrodes may be formed of the same conductive metal as that of the internal electrodes, but the present disclosure is not limited thereto. For example, the conductive metal may be copper (Cu), silver (Ag), nickel (Ni), or the like, alone, or alloys thereof.

The band surfaces of the external electrodes 41 and 42 formed on the conductive pattern layers may be formed by a plating process using the conductive pattern layers as seed layers, and the head surfaces of the external electrodes formed on both end surfaces of the ceramic body in the length direction L may be formed by a dipping method, a plating method, and the like, but the present disclosure is not limited thereto.

The first and second external electrodes formed on both end surfaces of the ceramic body in the length direction L, electrically connected to the internal electrodes, may include first and second base electrodes and plating layers formed on the first and second base electrodes by a plating process, and the plating layers may be extended onto the conductive pattern layers formed on one surface of the ceramic body in the thickness direction T by a plating process.

A method of forming the first and second base electrodes is not particularly limited, but, for example, may be formed by applying the conductive paste containing the conductive metal and then performing a sintering process. The head surfaces and the band surfaces of the first and second external electrodes may be formed by a plating process using the first and second base electrodes and the conductive pattern layers as seed layers.

A description of the same portions as the features of the multilayer ceramic electronic component according to the embodiment of the present disclosure described above will be omitted herein.

Printed Circuit Board Having Multilayer Ceramic Electronic Component

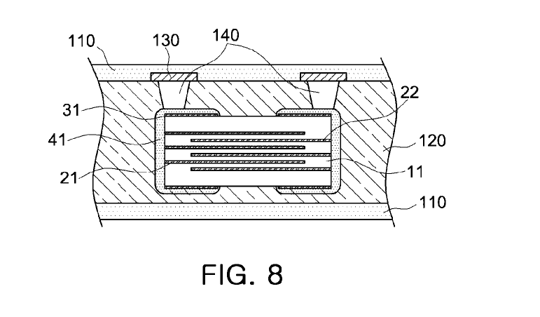

FIG. 8 is a cross-sectional view showing a printed circuit board having the multilayer ceramic electronic component according to an exemplary embodiment of the present disclosure.

Referring to FIG. 8, a printed circuit board having the multilayer ceramic electronic component according to an exemplary embodiment of the present disclosure may include the multilayer ceramic electronic component embedded in an insulation layer 120 thereof.

The printed circuit board may have the insulation layer 120, and as shown in FIG. 8, may include conductive patterns 130, conductive via holes 140, and solder resists 110 configuring various forms of interlayer circuits, if needed.

The multilayer ceramic electronic component to be embedded in the board may include: the ceramic body 10 including the dielectric layers 11 and having both end surfaces in the length direction L, both surfaces in the width direction W, and both surfaces in the thickness direction T; the first and second internal electrodes 21 and 22 formed to be alternately exposed to both end surfaces of the ceramic body 10 in the length direction L, having the dielectric layers 11 interposed therebetween; conductive pattern layers 31 and 32 formed on at least one surface of the ceramic body 10 in the thickness direction T; and the first and second external electrodes 41 and 42 formed on both end surfaces of the ceramic body 10 in the length direction L, the first external electrode being electrically connected to the first internal electrode 21 and the second external electrode 42 being electrically connected to the second internal electrode 22, wherein the first and second external electrodes 41 and 42 are extended onto the conductive pattern layers 31 and 32 formed on the at least one end surface of the ceramic body 10 in the thickness direction T.

In the multilayer ceramic electronic component to be embedded in the board, the conductive pattern layers 31 and 32 are formed on the surface of the ceramic body 10 in the thickness direction T, such that the band surfaces of the external electrodes 41 and 42 having a predetermined length or greater may be uniformly and more thinly formed on the conductive pattern layers 31 and 32 by plating. Therefore, a step portion between the external electrodes and the ceramic body may be decreased, and the occurrence of delamination may be prevented.

In addition, the conductive pattern layers 31 and 32 may be formed on the surface of the ceramic body 10 in the thickness direction T, and the band surfaces of the external electrodes 41 and 42 may be formed thereon by a plating process, such that each of widths BW1 and BW2 of the band surfaces of the first and second external electrodes 41 and 42 may be equal to or greater than 35% of the length of the ceramic body 10. In a case in which each of the widths BW1 and BW2 of the band surfaces is less than 35% of the length of the ceramic body 10, probability of the occurrence of defects may be increased during the processing of the via hole for connecting the external electrode to the external wiring.

Further, in the multilayer ceramic electronic component to be embedded in the board according to an exemplary embodiment of the present disclosure, the thickness of the cover layer adjacent to the surface of the ceramic body on which the band surfaces of the external electrodes 41 and 42 are formed may be decreased, such that a current path in the multilayer ceramic capacitor may be decreased, whereby equivalent series inductance (ESL) may also be decreased.

Features other than the above-mentioned feature are the same as those of the multilayer ceramic electronic component to be embedded in a board according to the exemplary embodiment of the present disclosure described above. Therefore, a description thereof will be omitted.

As set forth above, in a multilayer ceramic electronic component to be embedded in a board according to exemplary embodiments of the present disclosure, a thickness of a ceramic body in an overall chip may be increased by not allowing an increase in a thickness of an external electrode to occur, while forming a band surface of the external electrode having a predetermined length or greater for connecting the external electrode to an external wiring through a via hole, such that chip strength may be improved and the occurrence of damage such as breakage, or the like may be prevented.

In addition, a step generated in an amount equal to the thickness of the external electrode may be decreased, such that the occurrence of delamination may be decreased at the time of embedding the multilayer ceramic electronic component in the board.

While exemplary embodiments have been shown and described above, it will be apparent to those skilled in the art that modifications and variations could be made without departing from the spirit and scope of the present disclosure as defined by the appended claims.

What is claimed is:

1. A multilayer ceramic electronic component comprising:
a ceramic body including dielectric layers and having end surfaces in a length direction, both surfaces in a width direction, and both surfaces in a thickness direction;
first and second internal electrodes formed to be alternately exposed to the end surfaces of the ceramic body in the length direction, the dielectric layers being interposed between first and second internal electrodes;
conductive pattern layers formed on at least one surface of the ceramic body in the thickness direction; and
first and second external electrodes formed on the end surfaces of the ceramic body in the length direction, the first external electrode being electrically connected to the first internal electrode and the second external electrode being electrically connected to the second internal electrode,
wherein the first and second external electrodes are extended onto the conductive pattern layers formed on the least one surface of the ceramic body in the thickness direction.

2. The multilayer ceramic electronic component of claim 1, wherein a thickness of the ceramic body is equal to or greater than 80% of an overall thickness of the multilayer ceramic electronic component including the external electrodes.

3. The multilayer ceramic electronic component of claim 1, wherein an overall thickness of the multilayer ceramic electronic component including the external electrodes is 110 μm or less.

4. The multilayer ceramic electronic component of claim 1, wherein the conductive pattern layers contain at least one selected from a group consisting of copper (Cu), nickel (Ni), palladium (Pd), platinum (Pt), gold (Au), silver (Ag), and lead (Pb).

5. The multilayer ceramic electronic component of claim 1, wherein when a thickness of band surfaces of the first and second external electrodes extended on the conductive pattern layers and formed on the least one surface of the ceramic body in the thickness direction is defined as tp, tp 20 μm is satisfied.

6. The multilayer ceramic electronic component of claim 1, wherein the conductive pattern layers are formed to be separated from each other on both end portions of the at least one surface of the ceramic body in the thickness direction.

7. The multilayer ceramic electronic component of claim 1, wherein when widths of band surfaces of the first and second external electrodes extended onto the conductive pattern layers and formed on the at least one surface of the ceramic body in the thickness direction are defined as BW1 and BW2, each of BW1 and BW2 is equal to or greater than 35% of a length of the ceramic body.

8. The multilayer ceramic electronic component of claim 1, wherein the conductive pattern layers and the first and second external electrodes extended onto the conductive pattern layers are only formed on one surface of the ceramic body in the thickness direction.

9. The multilayer ceramic electronic component of claim 7, wherein the ceramic body includes an active layer including the first and second internal electrodes to form capacitance; and
upper and lower cover layers formed on upper and lower portions of the active layer, and
when a thickness of the cover layer adjacent to one surface of the ceramic body on which the band surfaces of the first and second external electrodes are extended onto the conductive pattern layers is defined as tc1 and a thickness of the cover layer adjacent to the other surface of the ceramic body on which the band surfaces of the first and second external electrodes are not formed is defined as tc2, tc1/tc2 is less than 1.

10. The multilayer ceramic electronic component of claim 1, wherein the first and second external electrodes extended onto the conductive pattern layers are formed by plating.

11. A multilayer ceramic electronic component to be embedded in a board, comprising:
a ceramic body including dielectric layers and having both end surfaces in a length direction, both surfaces in a width direction, and both surfaces in a thickness direction;
first and second internal electrodes formed to be alternately exposed to the both end surfaces of the ceramic body in the length direction, having the dielectric layers interposed therebetween;
conductive pattern layers formed on at least one surface of the ceramic body in the thickness direction; and
first and second external electrodes formed on the both end surfaces of the ceramic body in the length direction, the first external electrode being electrically connected to the first internal electrode and the second external electrode being electrically connected to the second internal electrode,
wherein the first and second external electrodes include first and second base electrodes formed on the both end surfaces of the ceramic body in the length direction and plating layers formed on the first and second base electrodes, the plating layers being extended onto the conductive pattern layers formed on the least one surface of the ceramic body in the thickness direction.

12. A manufacturing method of a multilayer ceramic electronic component to be embedded in a board, the manufacturing method comprising:
preparing a plurality of ceramic sheets;
forming an internal electrode pattern on each of the ceramic sheets using a conductive paste;
forming a ceramic body including first and second internal electrodes opposed to each other therein by stacking the ceramic sheets having the internal electrode pattern formed thereon;
compressing and sintering the ceramic body; and
forming conductive patterns on at least one surface of the ceramic body in a thickness direction using the conductive paste; and
forming first and second external electrodes to contact the first and second internal electrodes exposed to both end surfaces of the ceramic body in a length direction to thereby be electrically connected thereto,
wherein the first and second external electrodes are formed to be extended onto the conductive patterns formed on the at least one surface of the ceramic body in the thickness direction.

13. The manufacturing method of claim 12, wherein the forming of the first and second external electrodes includes forming first and second base electrodes on the both end surfaces of the ceramic body in the length direction and forming plating layers on the first and second base electrodes and the conductive patterns.

14. The manufacturing method of claim 12, wherein the conductive paste for forming the conductive patterns contains at least one selected from a group consisting of copper (Cu), nickel (Ni), palladium (Pd), platinum (Pt), gold (Au), silver (Ag), and lead (Pb).

15. The manufacturing method of claim 12, wherein the forming of the conductive patterns includes:
disposing sheets having the conductive patterns formed on one surfaces thereof on both surfaces of the ceramic body in the thickness direction, the conductive patterns being disposed in the same direction; and
removing an outermost sheet disposed on one surface of the ceramic body in the thickness direction, among the sheets having the conductive patterns disposed on the both surfaces of the ceramic body in the thickness direction to thereby expose the conductive patterns.

16. The manufacturing method of claim 12, wherein the conductive patterns are formed to be separated from each other on both end portions of the at least one surface of the ceramic body in the thickness direction.

17. A printed circuit board having a multilayer ceramic electronic component, comprising:
an insulation substrate; and
the multilayer ceramic electronic component embedded in the board and including a ceramic body including dielectric layers and having both end surfaces in a length direction, both surfaces in a width direction, and both surfaces in a thickness direction; first and second internal electrodes formed to be alternately exposed to the both end surfaces of the ceramic body in the length direction, having the dielectric layers interposed therebetween; conductive pattern layers formed on at least one surface of the ceramic body in the thickness direction; and first and second external electrodes formed on the both end surfaces of the ceramic body in the length direction, the first external electrode being electrically connected to the first internal electrode and the second external electrode being electrically connected to the second internal electrode, wherein the first and second external electrodes are extended onto the conductive pattern layers formed on the least one surface of the ceramic body in the thickness direction.

18. The printed circuit board of claim 17, wherein a thickness of the ceramic body is equal to or greater than 80% of an overall thickness of the multilayer ceramic electronic component including the external electrodes.

19. The printed circuit board of claim 17, wherein an overall thickness of the multilayer ceramic electronic component including the external electrodes is 110 μm or less.

20. The printed circuit board of claim 17, wherein when a thickness of band surfaces of the first and second external electrodes extended onto the conductive pattern layers and formed on the least one surface of the ceramic body in the thickness direction is defined as tp, tp 20 μm is satisfied.

21. The printed circuit board of claim 17, wherein when widths of band surfaces of the first and second external electrodes extended onto the conductive pattern layers and formed on the at least one surface of the ceramic body in the thickness direction are defined as BW1 and BW2, each of BW1 and BW2 is equal to or greater than 35% of a length of the ceramic body.

22. The printed circuit board of claim 17, wherein the conductive pattern layers and the first and second external electrodes extended onto the conductive pattern layers are only formed on one surface of the ceramic body in the thickness direction.

23. The printed circuit board of claim 17, wherein the ceramic body includes an active layer including the first and second internal electrodes to form capacitance; and
upper and lower cover layers formed on upper and lower portions of the active layer, and
when a thickness of the cover layer adjacent to one surface of the ceramic body on which the band surfaces of the first and second external electrodes are extended onto the conductive pattern layers is defined as tc1 and a thickness of the cover layer adjacent to the other surface of the ceramic body on which the band surfaces of the first and second external electrodes are not formed is defined as tc2, tc1/tc2 is less than 1.
